(19) United States
(12) Patent Application Publication
(10) Pub. No.: US 2023/0159385 A1
(43) Pub. Date: May 25, 2023

(54) SUBSTRATE, METHOD FOR SEPARATING THE SUBSTRATE, AND DISPLAY PANEL

(71) Applicant: Shenzhen China Star Optoelectronics Semiconductor Display Technology Co., Ltd., Shenzhen, Guangdong (CN)

(72) Inventor: Ying YAN, Shenzhen, Guangdong (CN)

(73) Assignee: Shenzhen China Star Optoelectronics Semiconductor Display Technology Co., Ltd., Shenzhen, Guangdong (CN)

(21) Appl. No.: 17/051,300

(22) PCT Filed: Oct. 10, 2020
(86) PCT No.: PCT/CN2020/120062

§ 371 Date: Oct. 28, 2020

(30) Foreign Application Priority Data
Aug. 10, 2020 (CN) 202010797677.8

(51) Int. Cl. C03C 23/00; C03C 17/36; C03C 17/38; C03C 17/42

(52) U.S. Cl. CPC C03C 23/0025; C03C 17/38; C03C 17/42; C03C 17/3626; C03C 17/3642; C03C 17/3644; C03C 17/3649; C03C 2217/228; C03C 2217/252; C03C 2217/256; C03C 2217/281

(57) ABSTRACT

A substrate, a method for separating the substrate, and a display panel are provided. The substrate is disposed on a glass substrate. The substrate includes a substrate layer and a sacrificial layer. The sacrificial layer disposed between the substrate layer and the glass substrate, and is configured to share the force exerted on the substrate layer when the substrate is being separated from the glass substrate.

### FIELD OF INVENTION

This disclosure relates to a field of display technology, in particular to the manufacture of display devices, and more particularly to a substrate, a method for separating the substrate, and a display panel.

### BACKGROUND OF INVENTION

Flexible organic light emitting diode (OLED, organic electro-laser display) displays have the characteristics of bendability, thinness, high refresh rates, and low power consumption. The key is that flexible OLEDs use flexible materials, such as polyimide, as flexible substrates.

When manufacturing a flexible OLED display panel, it is necessary to prepare a flexible substrate and relevant film layers on a glass substrate first, and then separate the flexible substrate from the glass substrate through a laser lift off (LLO) process. However, particles on a surface of the glass substrate may block a laser passing through, so that the molecular bonds between the glass substrate and the flexible substrate near the particles cannot be completely broken. When the flexible substrate is separated from the glass substrate, the flexible substrate is subjected to great stress, and the relevant film layers on the flexible substrate are damaged, which reduces the yield of the flexible OLED display panel.

Therefore, it is necessary to provide a substrate, a method for separating the substrate, and a display panel that can reduce the probability of damage to the relevant film layers on the flexible substrate.

### SUMMARY OF INVENTION

### Technical Problems

The disclosure provides a substrate, a method for separating the substrate, and a display panel. A sacrificial layer is disposed between a substrate layer in a substrate and a glass substrate for disposing the substrate. The sacrificial layer is configures to share the force exerted on the substrate when the substrate is being separated from the glass substrate.

### Technical Solutions

The disclosure provides a substrate. The substrate is disposed on a glass substrate. The substrate comprises:
a substrate layer; and
a sacrificial layer disposed between the substrate layer and the glass substrate, and the sacrificial layer is configured to share a force exerted on the substrate layer when the substrate is being separated from the glass substrate.

In one embodiment of the disclosure, the substrate layer is a flexible substrate layer.

In one embodiment of the disclosure, the sacrificial layer comprises a first sacrificial layer, and the first sacrificial layer is configured to be stripped off from the glass substrate under a laser irradiation.

In one embodiment of the disclosure, a material of the first sacrificial layer comprises a plastic material.

In one embodiment of the disclosure, the sacrificial layer further comprises a second sacrificial layer disposed between the substrate layer and the first sacrificial layer, and the second sacrificial layer is configured to block the laser irradiation to the substrate layer.

In one embodiment of the disclosure, a material of the second sacrificial layer comprises at least one of aluminum and silver.

In one embodiment of the disclosure, a thickness of the first sacrificial layer is less than a thickness of the substrate layer.

In one embodiment of the disclosure, materials of the first sacrificial layer and materials of the substrate layer are the same or different.

The disclosure further provides a display panel. The display panel comprises a substrate as the above mentioned.

In one embodiment of the disclosure, the display panel further comprises: an element layer disposed on a side of the substrate away from the glass substrate; and a buffer layer disposed between the element layer and the substrate, and the buffer layer is configured to share the force exerted on the element layer when the substrate is being separated from the glass substrate.

In one embodiment of the disclosure, the buffer layer comprises a first buffer layer and a second buffer layer laminated in layers, a material of the first buffer layer comprises silicon nitride, and a material of the second buffer layer comprises silicon oxide.

The disclosure further provides a method for separating a substrate. The method comprises:
providing a glass substrate;
forming the substrate on the glass substrate, wherein the substrate comprises a substrate layer and a sacrificial layer, the sacrificial layer is disposed between the substrate layer and the glass substrate, and the sacrificial layer is configured to share a force exerted on the substrate layer when the substrate is being separated from the glass substrate;
irradiating with a laser from a side of the glass substrate, so that the substrate and the glass substrate are stripped off; and separating the substrate from the glass substrate.

In one embodiment of the disclosure, the step of forming the substrate on the glass substrate further comprises: forming a first sacrificial layer on the glass substrate, and wherein the first sacrificial layer is configured to be stripped off from the glass substrate under a laser irradiation.

In one embodiment of the disclosure, after the step of forming the first sacrificial layer on the glass substrate, the method further comprises:

forming a second sacrificial layer on the first sacrificial layer, and the second sacrificial layer is configured to block the laser irradiation to the substrate layer.

### Advantageous Effects

Advantageous effects of the disclosure are as follows. The disclosure provides a substrate, a method for separating the substrate, and a display panel. The substrate is disposed on a glass substrate. The substrate comprises a substrate layer and a sacrificial layer disposed between the substrate layer and the glass substrate. The sacrificial layer is configured to share the force acting on the substrate layer when the substrate is being separated from the glass substrate. The force exerted on the substrate can be reduced, and the damage rate of the relevant film layers on the substrate is further reduced, so as to improve the yield of the display panel.

### DESCRIPTION OF DRAWINGS

In order to more clearly illustrate the embodiments of the disclosure or the technical solutions in the prior art, the following briefly introduces the accompanying drawings used in the embodiments. Obviously, the drawings in the following description merely show some of the embodiments of the disclosure. As regards one of ordinary skill in the art, other drawings can be obtained in accordance with these accompanying drawings without making creative efforts.

FIG. 1 is a schematic cross-sectional diagram of a substrate of an embodiment of the disclosure.

FIG. 2 is a schematic cross-sectional diagram of another substrate of an embodiment of the disclosure.

FIG. 3 is a schematic cross-sectional diagram of another substrate of an embodiment of the disclosure.

FIG. 4 is a schematic cross-sectional diagram of a display panel of an embodiment of the disclosure.

FIG. 5 is a schematic flowchart of a method for separating the substrate provided in an embodiment of the disclosure.

FIG. 6 is a schematic diagram of a scene of the method for separating the substrate provided in an embodiment of the disclosure.

### DETAILED DESCRIPTION OF PREFERRED EMBODIMENTS

The technical solutions in the embodiments of the disclosure will be described clearly and completely below with reference to the drawings in the embodiments of the disclosure. Obviously, the described embodiments are only a part of the embodiments of the disclosure, but not all the embodiments. Based on the embodiments in the disclosure, all other embodiments obtained by those skilled in the art without creative efforts fall within the scope of the disclosure.

In the description of this disclosure, it should be understood that the orientation or positional relationship indicated by the terms “upper”, “near”, “far away”, “surface”, etc. are based on the orientation or positional relationship shown in the drawings. For example, “Upper” only indicates that it is above the object, and specifically refers to directly above, obliquely above, and the upper surface, and the two can be in a non-contact state, while “surface” refers to the direct contact between two objects. The orientation or positional relationship is only for the convenience of describing the disclosure and simplifying the description, rather than indicating or implying that the device or element must have a specific orientation, be constructed and operated in a specific orientation, and therefore cannot be understood as a limitation of the disclosure. It should be noted that the term “thickness” is a neutral word, and does not mean that it is thick or thin. It just means that there is a reference value. The value is uncertain and will be determined according to the actual situation.

In addition, the terms “first” and “second” are only used for descriptive purposes, and cannot be understood as indicating or implying relative importance or implicitly indicating the number of indicated technical features. Therefore, the features defined with “first” and “second” may explicitly or implicitly include one or more of the features. In the description of this application, “multiple” means two or more than two, unless otherwise specifically defined.

In the drawings, elements with similar structures are indicated by the same reference numerals. The term “embodiment” used in this disclosure means that a specific feature, structure or characteristic described in conjunction with the embodiments may be included in at least one embodiment of the disclosure. The terms in various paragraphs in the specification does not necessarily refer to the same embodiment, nor is it an independent or alternative embodiment mutually exclusive with other embodiments. It is explicitly and implicitly understood by those skilled in the art that the embodiments described herein may be combined with other embodiments.

The disclosure provides a substrate. The substrate includes but is not limited to the following embodiments and combinations of the following embodiments.

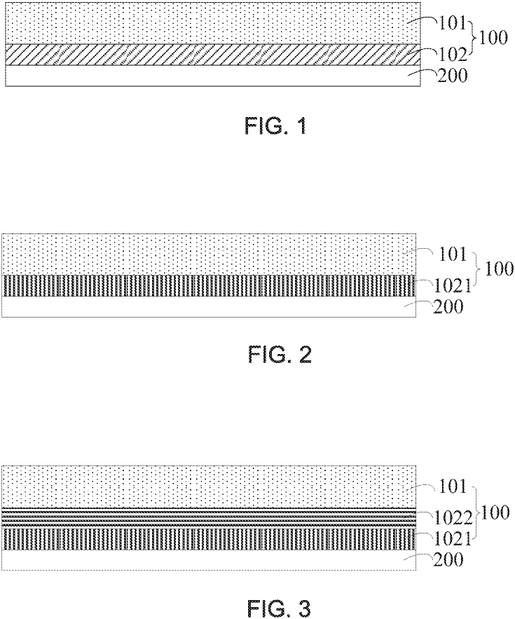

In one embodiment, referring to FIG. 1, the substrate 100 is disposed on a glass substrate 200. The substrate 100 comprises: a substrate layer 101, and a sacrificial layer 102 disposed between the substrate layer 101 and the glass substrate 200. The sacrificial layer 102 is configured to share a force exerted on the substrate layer 101 when the substrate 100 is being separated from the glass substrate 200.

A material of the glass substrate 200 includes at least one of quartz powder, strontium carbonate, barium carbonate, boric acid, boric anhydride, aluminum oxide, calcium carbonate, barium nitrate, magnesium oxide, tin oxide, and zinc oxide. It can be understood that a hardness of the glass substrate 200 is greater than a hardness of the substrate 100 to support the substrate 100 and other film layers on the substrate 100.

The substrate layer 101 is a flexible substrate. Further, the substrate layer 101 is a polymer material substrate, and the material of the polymer material substrate includes at least one of polyethylene, polypropylene, polystyrene, polyethylene terephthalate, polyethylene terephthalate and polyimide. It can be understood that using the polymer material substrate as the substrate layer 101 has the advantages of high flexibility, light weight, impact resistance and the like.

In particular, when the substrate 100 is being separated from the glass substrate 200, since the sacrificial layer 102 is disposed between the substrate layer 101 and the glass substrate 200, the sacrificial layer 102 will be subjected to a larger force than the substrate and the glass substrate. Therefore, the sacrificial layer 102 can prevent the force of the glass substrate 200 from directly exerting on the substrate layer 101, and reduce the force on the substrate layer 101. The probability of damage to other film layers on the substrate 100 is reduced.

In an embodiment, as shown in FIG. 2, the sacrificial layer 102 includes a first sacrificial layer 1021, and the first sacrificial layer 1021 is configured to be stripped off from the glass substrate 200 under a laser irradiation.

It can be understood that when the laser irradiates from one side of the glass substrate 200, by stripping the first sacrificial layer 1021 from the glass substrate 200, the substrate layer 101 is stripped off from the glass substrate 200, and the substrate layer 101 does not directly contact the glass substrate 200, reducing the probability of the damage to the substrate layer 101 and the other film layers the substrate layer 101.

In an embodiment, a material of the first sacrificial layer 1021 includes a plastic material. For example, the material of the first sacrificial layer 1021 includes at least one of polyethylene terephthalate, polyethylene naphthalate and polyimide. It can be understood that due to the short wavelength of the laser, the first sacrificial layer 1021 made of the plastic material has a high absorption rate to the laser under the laser irradiation. The first sacrificial layer 1021 will be evaporated, so that the chemical bond on a surface of the first sacrificial layer 1021 in contact with the glass substrate 200 is broken. The adsorption force between the first sacrificial layer 1021 and the glass substrate 200 is lost, so that the first sacrificial layer 1021 can be stripped off from the glass substrate 200.

Besides, the material of the first sacrificial layer 1021 and the material of the substrate layer 101 are the same or different. Further, a thickness of the first sacrificial layer 1021 is less than a thickness of the substrate layer 101. It can be understood that the first sacrificial layer 1021 is stripped off from the glass substrate 200 under the laser irradiation. That is to say, a loss of the first sacrificial layer 1021 is inevitable after being stripped from the glass substrate 200. Moreover, the ultimate purpose of the first sacrificial layer 1021 is to protect the substrate layer 101, and may no longer have a substantial effect after being stripped off from the glass substrate 200. Thus, the thickness of the first sacrificial layer 1021 is set to be relatively small, and the costs can be saved.

In one embodiment, as shown in FIG. 3, the sacrificial layer 102 further includes a second sacrificial layer 1022, and the second sacrificial layer 1022 is disposed between the substrate layer 101 and the first sacrificial layer 1021. The second sacrificial layer 1022 is configured to block laser irradiation to the substrate layer 101.

It can be understood that when the energy of the laser on one side of the glass substrate 200 is large, the second sacrificial layer 1022 may not affect the stripping of the first sacrificial layer 1021 and the glass substrate 200. The second sacrificial layer 1022 is disposed on a side of the substrate layer 101 close to the glass substrate 200, so as to prevent the laser from directly irradiating the substrate layer 101, thereby preventing the chemical bond on the surface of the substrate layer 101 from being broken, and further preventing the substrate layer 101 and other film layers on the substrate layer 101 from peeling off.

Besides, when the material of the first sacrificial layer 1021 and the material of the substrate layer 101 are the same or have similar chemical properties, the material of the second sacrificial layer 1022 is an inorganic material. Since the properties of the material of the second sacrificial layer 1022 are different from those of the first sacrificial layer 1021 and the substrate layer 101, the second sacrificial layer 1022 can also differentiate the first sacrificial layer 1021 from the substrate layer 101. When the first sacrificial layer 1021 is peeled off from the glass substrate 200, it is avoided that the second sacrificial layer 1022 is affected by the similarity between the material of the second sacrificial layer 1022 and that of the first sacrificial layer 1021.

Furthermore, the material of the second sacrificial layer 1022 includes a metal material. It can be understood that the second sacrificial layer 1022 made of the metal material has a desirable reflectivity. When the laser on one side of the glass substrate 200 irradiates the second sacrificial layer 1022, the second sacrificial layer 1022 can not only block the laser from directly irradiating the substrate layer 101, but also can reflect part of the laser to the first sacrificial layer 1021, thereby increasing the amount of laser finally irradiating the first sacrificial layer 1021. Thus, the chemical bonds in the first sacrificial layer 1021 can be sufficiently broken to facilitate peeling the first sacrificial layer 1021 off from the glass substrate 200 later. Besides, the thickness of the second sacrificial layer 1022 made of the metal material is less than the thickness of the first sacrificial layer 1021. Since the second sacrificial layer 1022 needs to be capable of bending, the second sacrificial layer 1022 is set to be thinner than the first sacrificial layer 1021 for increasing the bendability of the substrate 100.

In an embodiment, the material of the second sacrificial layer 1022 includes at least one of aluminum and silver. It can be understood that the first sacrificial layer 1021 made of the plastic material has poor barrier ability to water vapor and oxygen. When water vapor and oxygen enter the second sacrificial layer 1022 through the first sacrificial layer 1021, the second sacrificial layer 1022 made of at least one of aluminum and silver may undergo oxidation reaction and form a dense oxide layer on the surface of the second sacrificial layer 1022. The oxide layer can prevent water vapor and oxygen from entering the substrate layer 101, prevent other film layers on the substrate layer 101 from being corroded, and improve the ability of the substrate 100 to block water vapor and oxygen.

The disclosure further provides a display panel, which includes but is not limited to any of the above-mentioned substrate.

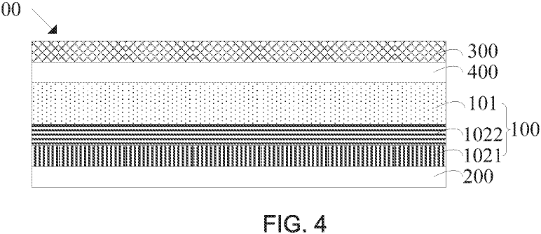

In one embodiment, as shown in FIG. 4, the display panel 00 further includes: an element layer 300 disposed on a side of the substrate 100 away from the glass substrate 200, a buffer layer 400 disposed between the element layer 300 and the substrate 100. The buffer layer 400 is configured to share the force exerted on the element layer 300 when the substrate 100 is being separated from the glass substrate 200.

The element layer 300 includes a plurality of thin film transistors and a plurality of wires, and the plurality of thin film transistors may be made of, for example, at least one of low-temperature polysilicon materials, oxide materials, or amorphous silicon materials.

It can be understood that the buffer layer 400 is disposed between the element layer 300 and the substrate 100. When the substrate 100 is being separated from the glass substrate 200, the arrangement of the buffer layer 400 increases a distance between the element layer 300 and the substrate 100 for preventing the direct contact between the element layer 300 and the substrate 100. It effectively reduces the force exerted on the element layer 300 and reduces the probability of damage to the plurality of thin film transistors, the plurality of wires and other elements in the element layer 300.

Moreover, the buffer layer 400 comprises a first buffer layer and a second buffer layer laminated in layers, a material of the first buffer layer comprises silicon nitride, and a material of the second buffer layer comprises silicon oxide. The relative positions of the first buffer layer and the second buffer layer are not limited. It can be understood that the buffer layer 400 can effectively prevent water vapor and oxygen from entering the element layer 300 when the buffer layer 400 meets the electrical requirements of a plurality of thin film transistors in the element layer 300, thereby improving the ability of the display panel 00 to block water vapor and oxygen.

The disclosure also provides a method for separating a substrate, which includes but is not limited to the following embodiments and a combination of the following embodiments.

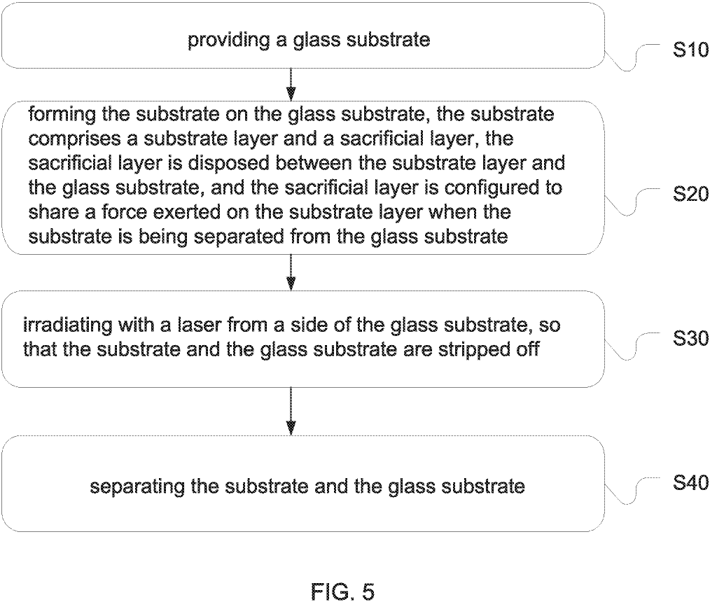

In one embodiment, as shown in FIG. 5, the method includes but is not limited to the following steps.

In a step S10, a glass substrate is provided.

A material of the glass substrate includes at least one of quartz powder, strontium carbonate, barium carbonate, boric acid, boric anhydride, alumina, calcium carbonate, barium nitrate, magnesium oxide, tin oxide and zinc oxide. It can be understood that the hardness of the glass substrate is greater than that of the substrate to support the substrate and other film layers on the substrate.

In a step S20, the substrate is formed on the glass substrate. The substrate comprises a substrate layer and a sacrificial layer. The sacrificial layer is disposed between the substrate layer and the glass substrate, and the sacrificial layer is configured to share the force exerted on the substrate layer when the substrate is being separated from the glass substrate.

The substrate layer is a flexible substrate. Further, the substrate layer is a polymer material substrate, and the material of the polymer material substrate includes at least one of polyethylene, polypropylene, polystyrene, polyethylene terephthalate, polyethylene terephthalate and polyimide. It can be understood that using the polymer material substrate as the substrate layer has the advantages of high flexibility, light weight, impact resistance and the like. Specifically, for example, when the material of the substrate is polyimide, the liquid polyimide can be first coated on the glass substrate, and then the liquid polyimide can be solidified to form the flexible substrate.

In particular, when the substrate is being separated from the glass substrate, since the sacrificial layer is disposed between the substrate layer and the glass substrate, the sacrificial layer will be subjected to a larger force than the substrate and the glass substrate. Therefore, the sacrificial layer can prevent the force of the glass substrate from directly exerting on the substrate layer, and reduce the force on the substrate layer. The probability of damage to other film layers on the substrate is reduced.

In an embodiment, the step S20 includes but is not limited to the following steps.

In a step S201, a first sacrificial layer is formed on the glass substrate. The first sacrificial layer is configured to be stripped off from the glass substrate under a laser irradiation.

It can be understood that when the laser irradiates from one side of the glass substrate, by stripping the first sacrificial layer from the glass substrate, the substrate layer is stripped off from the glass substrate, and the substrate layer does not directly contact the glass substrate, reducing the probability of the damage to the substrate layer and the other film layers the substrate layer.

In an embodiment, a material of the first sacrificial layer includes a plastic material. For example, the material of the first sacrificial layer 1021 includes at least one of polyethylene terephthalate, polyethylene naphthalate and polyimide. It can be understood that due to the short wavelength of the laser, the first sacrificial layer made of the plastic material has a high absorption rate to the laser under the laser irradiation. The first sacrificial layer will be evaporated, so that the chemical bond on a surface of the first sacrificial layer in contact with the glass substrate is broken. The adsorption force between the first sacrificial layer and the glass substrate is lost, so that the first sacrificial layer can be stripped off from the glass substrate.

Besides, the material of the first sacrificial layer and the material of the substrate layer are the same or different. Further, a thickness of the first sacrificial layer is less than a thickness of the substrate layer. It can be understood that the first sacrificial layer is stripped off from the glass substrate under the laser irradiation. That is to say, a loss of the first sacrificial layer is inevitable after being stripped from the glass substrate. Moreover, the ultimate purpose of the first sacrificial layer is to protect the substrate layer, and may no longer have a substantial effect after being stripped off from the glass substrate. Thus, the thickness of the first sacrificial layer is set to be relatively small, and the costs can be saved.

In an embodiment, the step S201 further includes but is not limited to the following steps.

In a step S202, a second sacrificial layer is formed on the first sacrificial layer. The second sacrificial layer is configured to block the laser irradiation to the substrate layer.

It can be understood that when the energy of the laser on one side of the glass substrate is large, the second sacrificial layer may not affect the stripping of the first sacrificial layer and the glass substrate. The second sacrificial layer is disposed on a side of the substrate layer close to the glass substrate, so as to prevent the laser from directly irradiating the substrate layer, thereby preventing the chemical bond on the surface of the substrate layer from being broken, and further preventing the substrate layer 101 and other film layers on the substrate layer from peeling off.

Besides, when the material of the first sacrificial layer and the material of the substrate layer are the same or have similar chemical properties, the material of the second sacrificial layer is an inorganic material. Since the properties of the material of the second sacrificial layer are different from those of the first sacrificial layer and the substrate layer, the second sacrificial layer can also differentiate the first sacrificial layer from the substrate layer. When the first sacrificial layer is peeled off from the glass substrate, it is avoided that the second sacrificial layer is affected by the similarity between the material of the second sacrificial layer and that of the first sacrificial layer.

Furthermore, the material of the second sacrificial layer includes a metal material. It can be understood that the second sacrificial layer made of the metal material has a desirable reflectivity. When the laser on one side of the glass substrate irradiates the second sacrificial layer, the second sacrificial layer can not only block the laser from directly irradiating the substrate layer, but also can reflect part of the laser to the first sacrificial layer, thereby increasing the amount of laser finally irradiating the first sacrificial layer. Thus, the chemical bonds in the first sacrificial layer can be sufficiently broken to facilitate peeling the first sacrificial layer off from the glass substrate later. Besides, the thickness of the second sacrificial layer made of the metal material is less than the thickness of the first sacrificial layer. Since the second sacrificial layer needs to be capable of bending, the second sacrificial layer is set to be thinner than the first sacrificial layer for increasing the bendability of the substrate.

In an embodiment, the material of the second sacrificial layer includes at least one of aluminum and silver. It can be understood that the first sacrificial layer made of the plastic material has poor barrier ability to water vapor and oxygen. When water vapor and oxygen enter the second sacrificial layer through the first sacrificial layer, the second sacrificial layer made of at least one of aluminum and silver may undergo oxidation reaction and form a dense oxide layer on the surface of the second sacrificial layer. The oxide layer can prevent water vapor and oxygen from entering the substrate layer, prevent other film layers on the substrate layer from being corroded, and improve the ability of the substrate to block water vapor and oxygen.

In a step S30, a side of the glass substrate is irradiated with a laser, so that the substrate and the glass substrate are peeled off.

The wavelength of the laser is 308 nanometers, the pulse width of the laser is 23 nanoseconds to 27 nanoseconds, and the energy density of the laser is about 200 joules per cubic centimeter.

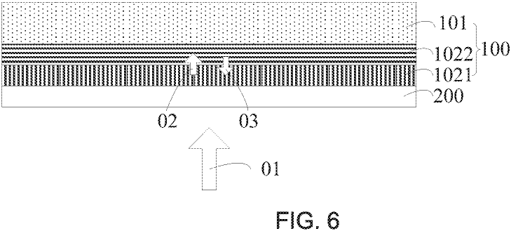

Specifically, as shown in FIG. 6, when the material of the second sacrificial layer 1022 includes a metal material, the second sacrificial layer 1022 has a desirable reflectivity. When the laser 01 irradiates from one side of the glass substrate 200, a part of the laser 02 in the laser 01 passes through the first sacrificial layer 1021 into the second sacrificial layer 1022, and another part of the laser 03 in the part of the laser 02 is reflected by the second sacrificial layer 1022 into the first sacrificial layer 1021, thereby increasing the amount of laser which finally irradiates the first sacrificial layer 1021.

It can be understood that when the amount of laser finally irradiated on the first sacrificial layer 1021 is large enough, the chemical bond in the first sacrificial layer 1021 can be fully broken, so that the adsorption force between the first sacrificial layer 1021 and the glass substrate 200 is reduced. When the adsorption force is reduced to a certain extent, the first sacrificial layer 1021 is stripped from the glass substrate 200.

In a step S40, the substrate and the glass substrate are separated.

Specifically, after the first sacrificial layer 1021 is stripped from the glass substrate 200, the first sacrificial layer 1021 can be removed from the glass substrate 200 to realize the separation of the substrate 100 and the glass substrate 200. Alternatively, the first sacrificial layer 1021 and the glass substrate 200 can be separated by slightly exerting force on the first sacrificial layer 1021 and the glass substrate 200.

It can be understood that after the substrate 100 is separated from the glass substrate 200, the first sacrificial layer 1021 can be retained in the substrate 100 to protect a lower surface of the substrate 100 in subsequent fabrication. If the first sacrificial layer 1021 is seriously damaged, and in the presence of the second sacrificial layer 1022, the energy of the laser can be increased in the step S30 to separate the first sacrificial layer 1021 from the second sacrificial layer 1022.

The disclosure provides a substrate, a method for separating the substrate, and a display panel. The substrate is disposed on a glass substrate. The substrate comprises a substrate layer and a sacrificial layer disposed between the substrate layer and the glass substrate. The sacrificial layer is configured to share the force acting on the substrate layer when the substrate is being separated from the glass substrate. The force exerted on the substrate can be reduced, and the damage rate of the relevant film layers on the substrate is further reduced, so as to improve the yield of the display panel.

As mentioned above, the disclosure provides a method for extracting information from a display panel, a device, and an electronic device. In this description, specific embodiments are used to explain the principle and implementation of this disclosure. The descriptions of the above embodiments are only used to help understand the method and core ideas of this disclosure. At the same time, for those skilled in the art, according to the principle of the disclosure, there will be changes in the specific implementation method and application scope. In summary, it is understood that many changes and modifications to the described embodiment can be carried out without departing from the scope and the spirit of the invention that is intended to be limited only by the appended claims.

What is claimed is:

1. A substrate, wherein the substrate is disposed on a glass substrate, and the substrate comprises:
a substrate layer;
a sacrificial layer disposed between the substrate layer and the glass substrate, and the sacrificial layer is configured to share a force exerted on the substrate layer when the substrate is being separated from the glass substrate.

2. The substrate according to claim 1, wherein the substrate layer is a flexible substrate layer.

3. The substrate according to claim 1, wherein the sacrificial layer comprises a first sacrificial layer, and the first sacrificial layer is configured to be stripped off from the glass substrate under a laser irradiation.

4. The substrate according to claim 3, wherein a material of the first sacrificial layer comprises a plastic material.

5. The substrate according to claim 4, wherein the sacrificial layer further comprises a second sacrificial layer disposed between the substrate layer and the first sacrificial layer, and the second sacrificial layer is configured to block the laser irradiation to the substrate layer.

6. The substrate according to claim 5, wherein a material of the second sacrificial layer comprises at least one of aluminum and silver.

7. The substrate according to claim 4, wherein a thickness of the first sacrificial layer is less than a thickness of the substrate layer.

8. The substrate according to claim 3, wherein materials of the first sacrificial layer and materials of the substrate layer are the same or different.

9. A display panel, comprising a substrate according to claim 1.

10. The display panel according to claim 9, wherein the display panel further comprises:
an element layer disposed on a side of the substrate away from the glass substrate; and
a buffer layer disposed between the element layer and the substrate, and the buffer layer is configured to share the force exerted on the element layer when the substrate is being separated from the glass substrate.

11. The display panel according to claim 10, wherein the buffer layer comprises a first buffer layer and a second buffer layer laminated in layers, a material of the first buffer layer comprises silicon nitride, and a material of the second buffer layer comprises silicon oxide.

12. A method for separating a substrate, comprising:
providing a glass substrate;
forming the substrate on the glass substrate, wherein the substrate comprises a substrate layer and a sacrificial layer, the sacrificial layer is disposed between the substrate layer and the glass substrate, and the sacrificial layer is configured to share a force exerted on the substrate layer when the substrate is being separated from the glass substrate;
irradiating with a laser from a side of the glass substrate, so that the substrate and the glass substrate are stripped off; and
separating the substrate from the glass substrate.

13. The method according to claim 12, wherein the step of forming the substrate on the glass substrate, wherein the substrate comprises a substrate layer and a sacrificial layer, the sacrificial layer is disposed between the substrate layer and the glass substrate, and the sacrificial layer is configured to share the force exerted on the substrate layer when the substrate is being separated from the glass substrate further comprises:
forming a first sacrificial layer on the glass substrate, and wherein the first sacrificial layer is configured to be stripped off from the glass substrate under a laser irradiation.

14. The method according to claim 13, wherein after the step of forming the first sacrificial layer on the glass substrate, the method further comprises:
forming a second sacrificial layer on the first sacrificial layer, and the second sacrificial layer is configured to block the laser irradiation to the substrate layer.
